(19) United States
(12) Patent Application Publication
(10) Pub. No.: US 2012/0152793 A1
(43) Pub. Date: Jun. 21, 2012

(54) DEVICE HOUSING AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); JIA HUANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/215,664

(22) Filed: Aug. 23, 2011

(30) Foreign Application Priority Data
Dec. 16, 2010 (CN) 201010591543.7

(51) Int. Cl. B65D 90/04; C23C 14/35; C23C 14/06

(52) U.S. Cl. 206/524.3; 204/192.1; 204/192.27

(57) ABSTRACT

A device housing is described. The device housing includes a transparent substrate, a color layer formed on an inside surface of the substrate, and a reflection layer formed on the color layer. The substrate is made of transparent glass or plastic. The color layer is a zirconium oxide layer. The reflection layer is a zirconium layer. The color value of the device housing has a L* coordinate between 30 and 35, an a* coordinate between 9 and 11, and a b* coordinate between −18 and −20 in the CIE LAB color system. A method for making the device housing is also described.

### BACKGROUND

1. Technical Field

The present disclosure relates to a device housing and a method for making the device housing.

2. Description of Related Art

To decorate housings of electronic devices, decorative layers may be formed on the housings by anodizing, painting, or vacuum depositing. However, the anodizing and painting processes are not environmentally friendly, and decorative layers formed by vacuum depositing may have not rich colors. Moreover, these decorative layers are usually prone to abrasions.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings like reference numerals designate corresponding parts throughout the several views.

FIG. 1 is a cross-sectional view of an exemplary embodiment of a device housing.

FIG. 2 is a schematic view of an exemplary embodiment of a vacuum sputtering device.

### DETAILED DESCRIPTION

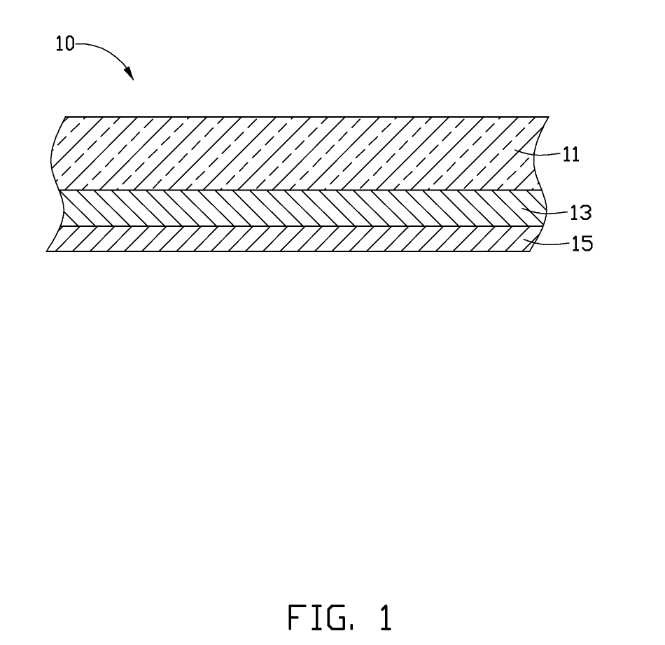

FIG. 1 shows a device housing 10 according to an exemplary embodiment. The device housing 10 includes a transparent substrate 11, a color layer 13 formed on a surface of the substrate 11, and a reflection layer 15 formed on the color layer 13.

The transparent substrate 11 may be made of glass or plastic.

The color layer 13 is formed on the inner surface of the substrate 11. An inner surface is the surface that will not be touched by users during use and faces the internal circuitry of the device, rather than its ambient environment. As such, the color layer 13 will be protected from abrasion and other potential damage. In an exemplary embodiment, the color layer 13 is a zirconium oxide (ZrO₂) layer formed by vacuum sputtering and presents a purple appearance. The color layer 13 has a thickness of about 300 nm-400 nm.

The reflection layer 15 may be a zirconium (Zr) layer formed by vacuum sputtering. The reflection layer 15 has a thickness of about 100 nm-200 nm. The reflection layer 15 has a high reflectivity, and reflects the light transiting towards the interface of the color layer 13 and the reflection layer 15 from the substrate 11. Thus, the device housing 10 has a vibrant color when observing through the substrate 11.

The color value of the exemplary embodiment of the device housing 10 has been testing. The test indicated that the color value of the device housing 10 had, in the CIE (international commission on illumination) LAB color system, a L* coordinate between 30 and 35, an a* coordinate between 9 and 11, and a b* coordinate between −18 and −20. The device housing 10 presents a bright purple appearance when observed through the substrate 11.

A method for making the device housing 10 may include the following steps:

The substrate 11 is pre-treated. The pre-treating process may include the following steps:

The substrate 11 is cleaned in an ultrasonic cleaning device (not shown) filled with ethanol or acetone.

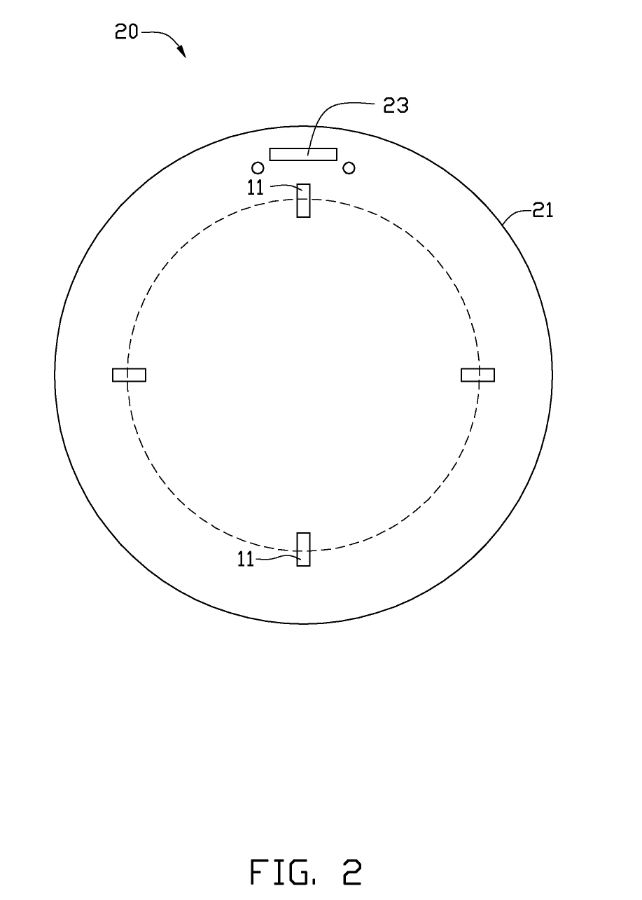

The color layer 13 may be magnetron sputtered on the pretreated substrate 11. Referring to FIG. 2, the substrate 11 may be positioned in a coating chamber 21 of a vacuum sputtering device 20. The coating chamber 21 is fixed with a zirconium target 23. The coating chamber 21 is then evacuated to about 8.0×10⁻³ Pa. Argon (Ar) gas having a purity of about 99.999% may be used as a working gas and is fed into the coating chamber 21 at a flow rate of about 300 standard-state cubic centimeters per minute (sccm) to about 500 sccm. Oxygen (O₂) may be used as a reaction gas and is fed into the coating chamber 21 at a flow rate of about 110 sccm-300 sccm. The internal temperature of the coating chamber 21 may be heated to about 60° C.-110° C. A power of about 3 kilowatt (kW)-4 kW is then applied on the zirconium target 23, and then zirconium atoms are sputtered off from the zirconium target 23. The zirconium atoms and oxygen atoms are then ionized in an electrical field in the coating chamber 21. The ionized zirconium chemically reacts with the ionized oxygen to deposit on the substrate 11 and form the color layer 13. During the depositing process, the substrate 11 may have a bias voltage of about −100 V to about −200 V. Depositing of the color layer 13 may take about 15 min-30 min.

The reflection layer 15 may be magnetron sputtered on the color layer 13. Magnetron sputtering of the reflection layer 15 is implemented in the coating chamber 21. The internal temperature of the coating chamber 21 may be maintained at about 60° C.-110° C. Argon gas may be used as a working gas and is fed into the coating chamber 21 at a flow rate of about 300 sccm-500 sccm. A power of about 3 kilowatt (kW)-4 kW is then applied on the zirconium target 23, and then zirconium atoms are sputtered off from the zirconium target 23 to deposit on the color layer 13 and form the reflection layer 15. During the depositing process, the substrate 11 may have a bias voltage of about −100 V to about −200 V. Depositing of the reflection layer 15 may take about 15 min-30 min.

It is to be understood that a transparent bonding layer may be formed between the substrate 11 and the color layer 13 to enhance the bond of the layers 13 and 15 to the substrate 11.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A device housing, comprising:
a transparent substrate;
a color layer formed on an inside surface of the substrate, the color layer being a zirconium oxide layer; and
a reflection layer formed on the color layer, the reflection layer being a zirconium layer;
wherein the color value of the device housing has a L* coordinate between 30 and 35, an a* coordinate between 9 and 11, and a b* coordinate between −18 and −20 in the CIE LAB color system.

2. The device housing as claimed in claim 1, the color layer having a thickness of about 300 nm-400 nm.

3. The device housing as claimed in claim 1, the color layer being purple.

4. The device housing as claimed in claim 1, the reflection layer having a thickness of about 100 nm-200 nm.

5. The device housing as claimed in claim 1, the transparent substrate being made of transparent glass or plastic.

6. A method for making a device housing, comprising:
providing a transparent substrate;
forming a color layer on an inside surface of the substrate by vacuum sputtering, the color layer being a zirconium oxide layer; and
forming a reflection layer on the color layer by vacuum sputtering, the reflection layer being a zirconium layer; the color value of the device housing having a L* coordinate between 30 and 35, an a* coordinate between 9 and 11, and a b* coordinate between −18 and −20 in the CIE LAB color system.

7. The method as claimed in claim 6, wherein forming the color layer uses a magnetron sputtering process, uses oxygen as a reaction gas, the oxygen having a flow rate of about 110 sccm-300 sccm; uses argon as a working gas, the argon having a flow rate of about 300 sccm-500 sccm; uses a zirconium target, the zirconium target being applied with a power of about 3 kW-4 kW; conducting the magnetron sputtering of the color layer at a temperature of about 60° C.-110° C. and for about 15 min-30 min

8. The method as claimed in claim 7, wherein the color layer has a thickness of about 300 nm-400 nm.

9. The method as claimed in claim 7, wherein the substrate has a bias voltage of about −100 V to about −200 V during sputtering of the color layer.

10. The method as claimed in claim 6, wherein forming the reflection layer uses a magnetron sputtering process, uses argon as a working gas, the argon having a flow rate of about 300 sccm-500 sccm; uses a zirconium target, the zirconium target being applied with a power of about 3 kW-4 kW; conducting the magnetron sputtering of the reflection layer at a temperature of about 60° C.-110° C. and for about 15 min-30 min.

11. The method as claimed in claim 10, wherein the reflection layer has a thickness of about 100 nm-200 nm.

12. The method as claimed in claim 10, wherein the substrate has a bias voltage of about −100 V to about −200 V during sputtering of the reflection layer.

13. The method as claimed in claim 6, further comprising a step of ultrasonic cleaning the substrate before forming the color layer.

14. The method as claimed in claim 6, wherein the transparent substrate is made of transparent glass or plastic.
